(19) United States
(12) Patent Application Publication
(10) Pub. No.: US 2026/0190897 A1
(43) Pub. Date: Jul. 2, 2026

(54) LIQUID SUPPLY APPARATUS AND MONITORING APPARATUS THEREOF

(71) Applicant: SEMES CO., LTD., Cheonan-si (KR)

(72) Inventor: Dae Kwan YUN, Cheonan-si (KR)

(21) Appl. No.: 19/329,598

(22) Filed: Sep. 16, 2025

(30) Foreign Application Priority Data
Dec. 30, 2024 (KR) 10-2024-0200715

(51) Int. Cl. H01L 21/67

(52) U.S. Cl. CPC H10P 72/0402

(57) ABSTRACT

A liquid supply apparatus includes a nozzle unit including a nozzle body, a housing cover coupled to the nozzle body by a plurality of fastening members, and a plurality of thin film-type pressure sensors inserted between the nozzle body and the housing cover, and a control portion configured to monitor whether the nozzle body and the housing cover are airtightly coupled to each other, based on measurement values of the plurality of thin film-type pressure sensors.

### CROSS-REFERENCE TO RELATED APPLICATION(S)

This application claims benefit of priority to Korean Patent Application No. 10-2024-0200715 filed on Dec. 30, 2024 in the Korean Intellectual Property Office, the disclosure of which is incorporated herein by reference in its entirety.

### TECHNICAL FIELD

The present disclosure relates to a liquid supply apparatus and a monitoring apparatus for measuring pressure of the liquid supply apparatus.

In general, a manufacturing process of a substrate for a semiconductor may be subdivided into a thin film process of depositing a thin film on a glass substrate, a photolithography process of forming the thin film into a desired pattern, and an etching process of etching the thin film according to the pattern. By repeatedly performing such processes, a substrate for a semiconductor may be manufactured.

For a substrate treatment process, a nozzle unit for discharging various treatment liquids may be provided. In the related art, sealing force may be guaranteed using a torque value of a bolt fastening a photoresist nozzle block. However, in a method according to the related art, loosening due to an operator's mistake or vibrations may not be detected.

In order to solve such an issue, a technology capable of monitoring airtightness of a nozzle unit structure in real time may be required.

### SUMMARY

An aspect of the present disclosure is to provide a liquid supply apparatus capable of real-time monitoring airtightness of a nozzle unit structure, and a monitoring apparatus thereof.

The aspects of the present disclosure is not limited thereto, and it may be understood by those skilled in the art that other technical issues not mentioned herein may be derived from the configurations described in the following specification and drawings.

According to an aspect of the present disclosure, there is provided a liquid supply apparatus including a nozzle unit including a nozzle body, a housing cover coupled to the nozzle body by a plurality of fastening members, and a plurality of thin film-type pressure sensors inserted between the nozzle body and the housing cover, and a control portion configured to monitor whether the nozzle body and the housing cover are airtightly coupled to each other, based on measurement values of the plurality of thin film-type pressure sensors.

According to another aspect of the present disclosure, there is provided a liquid supply apparatus including a treatment container having a treatment space for a substrate, a support portion provided in the treatment space, the support portion configured to support the substrate, a nozzle unit including a nozzle body, a housing cover coupled to the nozzle body by a plurality of fastening members, and a plurality of thin film-type pressure sensors inserted between the nozzle body and the housing cover, and a control portion configured to monitor whether the nozzle body and the housing cover are airtightly coupled to each other, based on measurement values of the plurality of thin film-type pressure sensors.

According to another aspect of the present disclosure, there is provided a method of monitoring a liquid supply apparatus, the method including measuring, by a plurality of thin film-type pressure sensors, pressure between a nozzle body and a housing cover, and monitoring, by a control portion, whether the nozzle body and the housing cover are airtightly coupled to each other, based on measurement values of the plurality of thin film-type pressure sensors.

According to example embodiments of the present disclosure, a liquid supply apparatus capable of real-time monitoring airtightness of a nozzle unit structure and a monitoring apparatus thereof may be provided, thereby preventing leakage of a treatment liquid, caused by loosening of a fastening member fastened to the nozzle unit structure, and managing a nozzle unit.

The effects of the present disclosure are not limited to the above-described effects, and it may be understood by those skilled in the art that other effects not mentioned may be derived from the configurations described in the following specification and drawings.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate treatment apparatus according to an example embodiment of the present disclosure;

FIG. 2 is a view of the substrate treatment apparatus of FIG. 1 taken along line A-A;

FIG. 3 is a view of the substrate treatment apparatus of FIG. 1 taken along line B-B;

FIG. 4 is a block diagram of a liquid supply apparatus according to an example embodiment of the present disclosure;

FIG. 5 is a perspective view of a nozzle unit according to an example embodiment of the present disclosure;

FIG. 6 is a flowchart of a method of monitoring a liquid supply apparatus according to an example embodiment of the present disclosure; and

FIG. 7 is a more detailed flowchart of operation S320 of FIG. 6.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

In addition, it will be understood that “comprises,” “comprising,” “includes,” and “including” specify the presence of stated features, integers, operations, operations, elements, components or a combination thereof, but do not preclude the presence or addition of one or more other features, integers, operations, operations, elements, components, and/or groups thereof.

The present disclosure may be implemented in various forms, and is not limited to the example embodiments described herein.

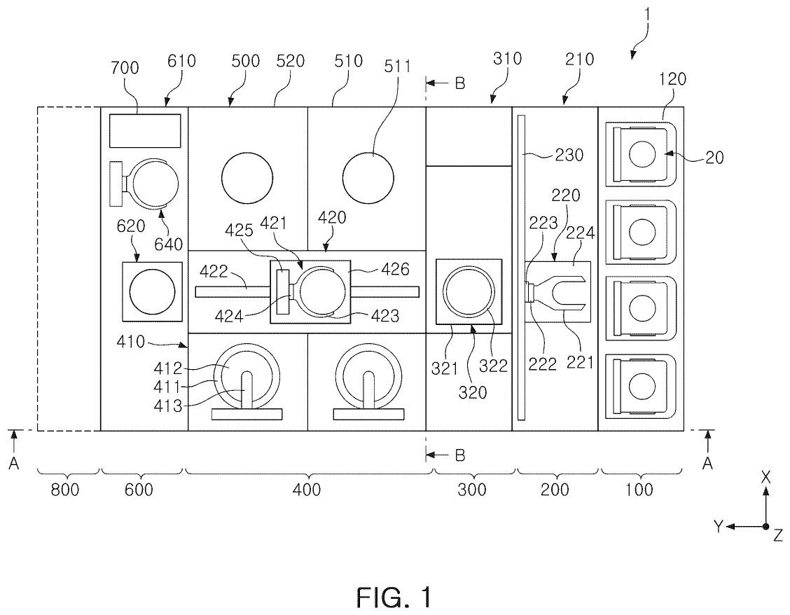

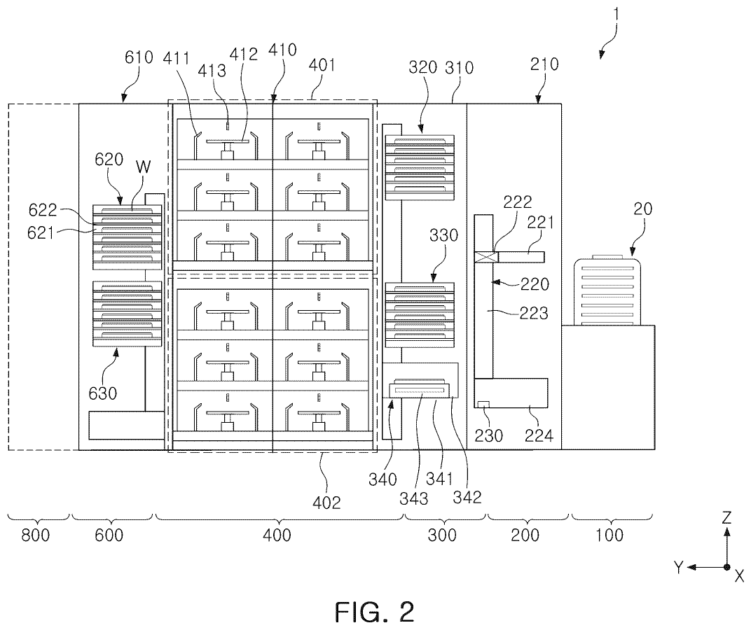

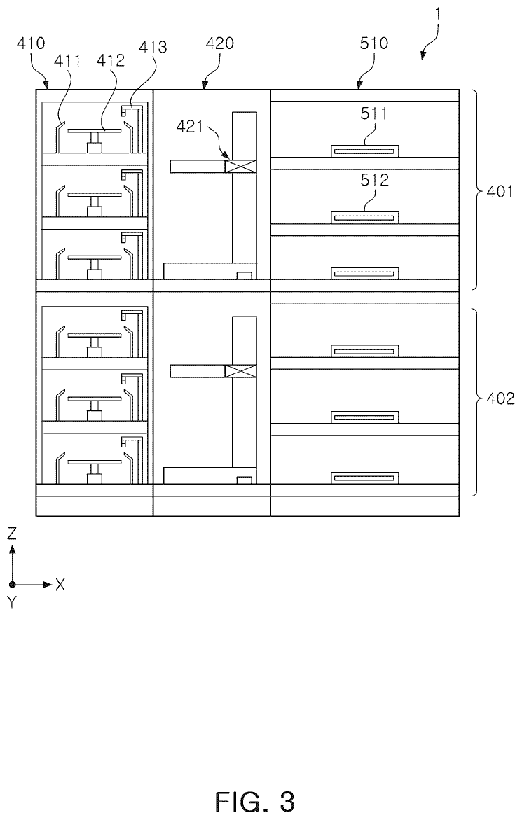

FIG. 1 is a top view of a substrate treatment apparatus according to an example embodiment of the present disclosure. FIG. 2 is a view of the substrate treatment apparatus of FIG. 1 taken along line A-A. FIG. 3 is a view of the substrate treatment apparatus of FIG. 1 taken along line B-B.

Referring to FIGS. 1 to 3, a substrate treatment apparatus 1 may include a load port 100, an index module 200, a buffer module 300, a coating and development module 400, and a purge module 700. The load port 100, the index module 200, the buffer module 300, the coating and development module 400, and an interface module 600 may be sequentially disposed in a line in one direction. The purge module 700 may be provided in the interface module 600. Alternatively, the purge module 700 may be provided in various positions such as a position to which an exposure device 800 at a rear end of the interface module 600 is connected, a side portion of the interface module 600, or the like.

Hereinafter, a direction in which the load port 100, the index module 200, the buffer module 300, the coating and development module 400, and the interface module 600 are disposed may be referred to as a first direction Y, a direction, perpendicular to the first direction Y when viewed from above, may be referred to as a second direction X, and a direction, perpendicular to each of the first direction Y and the second direction X, may be referred to as a third direction.

The substrate W may be moved in a state of being accommodated in a cassette 20. The cassette 20 may be sealed externally. As one example, a front open integrated pod (FOUP), having a door in front thereof, may be used as the cassette 20.

Hereinafter, the load port 100, the index module 200, the buffer module 300, the coating and development module 400, the interface module 600, and the purge module 700 will be described in detail.

The load port 100 may have a mounting table 120 on which the cassette 20 in which the substrate W is accommodated is disposed. The mounting table may be provided as a plurality of mounting tables 120, and the mounting tables 120 may be disposed in a line in the second direction X. FIG. 2 illustrates an example in which four mounting tables 120 are provided, but the number of mounting tables 120 may be changed.

The index module 200 may transfer the substrate W between the cassette 20 disposed on the mounting table 120 of the load port 100 and the buffer module 300. The index module 200 may include a frame 210, an index robot 220, and a guide rail 230. The frame 210 may have a substantially rectangular parallelepiped shape having an empty space therein, and may be disposed between the load port 100 and the buffer module 300. The frame 210 of the index module 200 may have a height, lower than that of a frame 310 of the buffer module 300. The index robot 220 and the guide rail 230 may be disposed in the frame 210. The index robot 220 may be provided such that a hand 221, directly handling the substrate W, is movable and rotatable in the first direction Y, the second direction X, and the third direction Z. The index robot 220 may include a hand 221, an arm 222, a support 223, and a pedestal 224. The hand 221 may be fixedly installed on the arm 222. The arm 222 may have a stretchable structure and a rotatable structure. The support 425 may be disposed such that a length direction thereof is the same as the third direction Z. The arm 222 may be coupled to the support 223 to be movable along the support 223. The support 223 may be fixedly coupled to the pedestal 224. The guide rail 230 may be disposed such that a length direction thereof is the same as the second direction X. The pedestal 224 may be coupled to the guide rail 230 to be linearly movable along the guide rail 230. In addition, although not illustrated, the frame 210 may further have a door opener for opening and closing a door of the cassette 20.

The buffer module 300 may include a frame 310, a first buffer 320, a second buffer 330, and a cooling chamber 340. The frame 310 may have a rectangular parallelepiped shape having an empty space therein, and may be disposed between the index module 200 and the coating and development module 400. The first buffer 320, the second buffer 330, and the cooling chamber 340 may be positioned in the frame 310. The cooling chamber 340, the second buffer 330, and the first buffer 320 may be sequentially disposed from the bottom in the third direction Z. The first buffer 320 may be positioned to have a height corresponding to that of a coating module 401 of the coating and development module 400, and the second buffer 330 and the cooling chamber 340 may be positioned to have a height corresponding to that of a development module 402 of the coating and development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each support 322 of the first buffer 320 and each support 332 of the second buffer 330. The housing 331 may have an opening in a direction in which the index robot 220 is provided, such that the index robot 220 may carry the substrate W into or out of the support 332 in the housing 331. The first buffer 320 may have a structure substantially similar to that of the second buffer 330. However, the housing 321 of the first buffer 320 may have openings in a direction in which a first buffer robot 360 is provided and in a direction in which a coating portion robot 421 positioned in the coating module 401 is provided. The number of supports 322 provided in the first buffer 320 may be equal to or different from the number of supports 332 provided in the second buffer 330. According to an example, the number of supports 332 provided in the second buffer 330 may be greater than the number of supports 322 provided in the first buffer 320.

The cooling chamber 340 may cool the substrate W. The cooling chamber 340 may include a housing 341 and a cooling plate 342. The cooling plate 342 may have an upper surface on which the substrate W is disposed, and a cooling means 343 for cooling the substrate W. Various methods, such as cooling using coolant or cooling using a thermoelectric element, may be used as the cooling means 343. In addition, the cooling chamber 340 may include a lift pin assembly for positioning the substrate W on the cooling plate 342. The housing 341 may have openings in a direction in which the index robot 220 is provided and in a direction in which a developing portion robot in the development module 402 is provided, such that the index robot 220 and the developing portion robot may carry the substrate W into or out of the cooling plate 342. In addition, doors for opening and closing the above-described openings may be provided in the cooling chamber 340.

In the above-described example embodiments, the buffer module 300 has been described to include the cooling chamber 340, but the present disclosure is not limited thereto. The cooling chamber 340 may be omitted, as necessary.

The coating module 401 may include a process of coating a photosensitive liquid, such as a photoresist, on the substrate W, and a heat treatment process, such as heating and cooling of the substrate W, before and after a resist coating process. The coating module 401 may have a coating chamber 410, a heat treatment chamber portion 500, and a conveyance chamber 420. The coating chamber 410, the conveyance chamber 420, and the heat treatment chamber portion 500 may be sequentially disposed in the second direction X. That is, with respect to the conveyance chamber 420, the coating chamber 410 may be disposed on one side of the conveyance chamber 420, and the heat treatment chamber portion 500 may be disposed on the other side of the conveyance chamber 420.

The coating chamber 410 may be provided as a plurality of coating chambers 410 in the third direction Z. In addition, as illustrated in FIG. 1, the coating chamber 410 may be provided as a plurality of coating chambers 410 in the first direction Y and as one coating chamber 410 in the first direction Y. The heat treatment chamber portion 500 may include a baking chamber 510 and a cooling chamber 520, and the baking chamber 510 and the cooling chamber 520 may be provided as a plurality of baking chambers 510 and a plurality of cooling chambers 520 in the third direction Z, respectively. The conveyance chamber 420 may be positioned to be parallel to the first buffer 320 of the first buffer module 300 in a first direction 12. The coating portion robot 421 and the guide rail 422 may be positioned in the conveyance chamber 420. The conveyance chamber 420 may have a substantially rectangular shape. The coating portion robot 421 may transfer the substrate W, between the baking chamber 510, the cooling chamber 520, the coating chamber 410, and the first buffer 320 of the first buffer module 300.

The guide rail 422 may be disposed such that a length direction thereof is parallel to the first direction Y. The guide rail 422 may guide the coating portion robot 421 to linearly move in the first direction Y. The coating portion robot 421 may have a hand 423, an arm 424, a support 425, and a pedestal 426. The hand 423 may be fixedly installed on the arm 424. The arm 424 may have a stretchable structure, such that the hand 423 may move in a horizontal direction. The support 425 may be disposed such that a length direction thereof is the same as the third direction Z. The arm 424 may be coupled to the support 425 so as to be linearly movable in the third direction Z along the support 425. The support 425 may be fixedly coupled to the pedestal 426, and the pedestal 426 may be coupled to the guide rail 422 so as to be movable along the guide rail 422.

All of the coating chambers 410 may have the same structure. However, types of treatment liquids, respectively used in the coating chambers 410, may be different from each other. A treatment liquid for forming a photoresist film or an antireflection film may be used as the treatment liquid.

The coating chamber 410 may coat a treatment liquid on the substrate W. A treatment unit, including a cup portion 411, a support portion 412, and a nozzle portion 413, may be provided in the coating chamber 410.

As one example, one treatment unit may be disposed in each coating chamber 410 in the first direction Y, but the present disclosure is not limited thereto, and two or more treatment units may be disposed in a single coating chamber 410. The treatment units may all have the same structure. However, types of treatment liquids, respectively used in the treatment units, may be different from each other.

The cup portion 411 of the coating chamber 410 may have a shape having an open upper portion. The support portion 412 may be disposed in the cup portion 411, and may support the substrate W. The support portion 412 may be rotatably provided. The nozzle portion 413 may supply a treatment liquid onto the substrate W disposed on the support portion 412. The treatment liquid may be coated on the substrate W in a spin-coating manner. In addition, the coating chamber 410 may further selectively include a nozzle (not illustrated) for supplying a cleaning liquid such as deionized water (DIW) to clean a surface of the substrate W on which the treatment liquid is coated, and a back rinse nozzle (not illustrated) for cleaning a lower surface of the substrate W.

In the baking chamber 510, when the substrate W is mounted by the coating portion robot 421, the substrate W may be heat-treated.

In the baking chamber 510, a pre-baking process of removing organic matter or moisture from a surface of the substrate W by heating the substrate W to a predetermined temperature may be performed before the treatment liquid is coated, or a soft baking process may be performed after the treatment liquid is coated on a wafer W, and a cooling process of cooling the substrate W may be performed after each heating process.

A heating plate 511 and a cooling plate 512 may be provided in the baking chamber 510. A cooling means such as coolant or a thermoelectric element may be provided in the cooling plate 512.

The cooling chamber 520 may perform a cooling process of cooling the substrate W before the treatment liquid is coated. The cooling chamber 520 may include a cooling plate. The cooling plate may include a cooling means in which various methods, such as cooling using a coolant or cooling using a thermoelectric element, are used to cool the substrate W.

The interface module 600 may connect the coating and development module 400 to an external exposure device 800. The interface module 600 may include an interface frame 610, a first interface buffer 620, a second interface buffer 630, and a conveyance robot 640, and the conveyance robot 640 may convey, to the exposure device 800, the substrate conveyed to the first and second interface buffers 620 and 630 after the coating and development module 400 is terminated. The first and second interface buffers 620 may include a housing 621 and a support 622, and the conveyance robot 640 and the coating portion robot 421 may carry the substrate W into/out of the support 622.

A liquid supply apparatus described below may be applicable to various types of chambers including the above-described coating chamber.

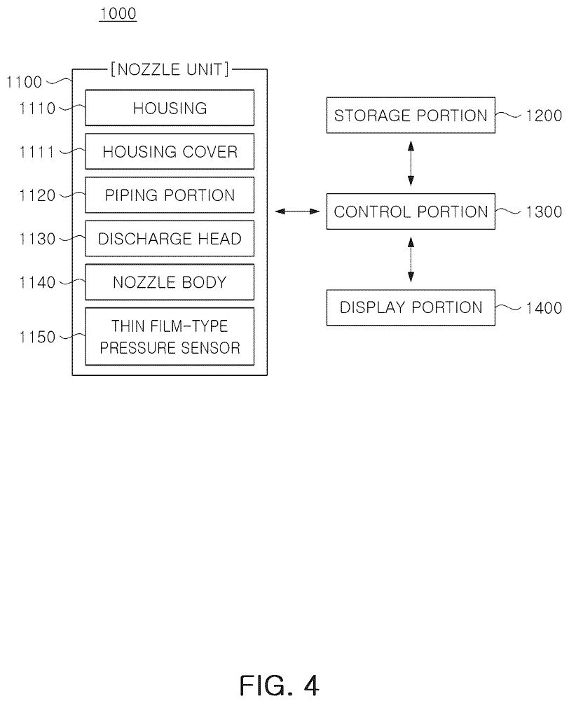

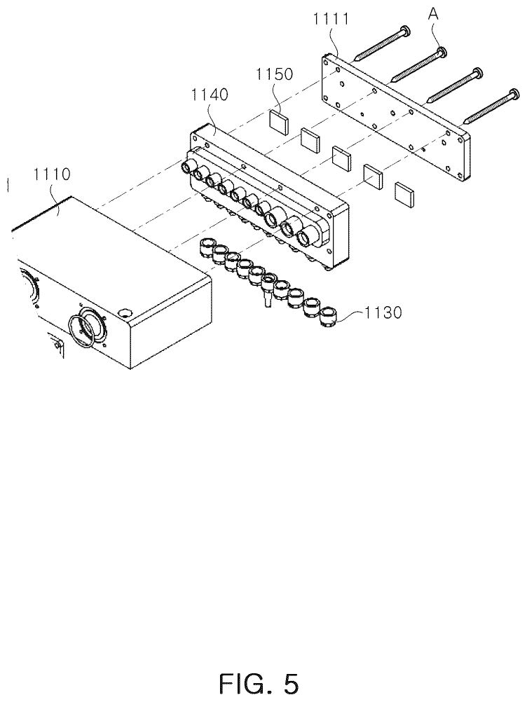

FIG. 4 is a block diagram of a liquid supply apparatus according to an example embodiment of the present disclosure. FIG. 5 is a perspective view of a nozzle unit according to an example embodiment of the present disclosure.

Referring to FIGS. 4 and 5, a liquid supply apparatus 1000 according to an example embodiment of the present disclosure may include a nozzle unit 1100, a storage portion 1200, a control portion 1300, and a display portion 1400.

The nozzle unit 1100 may include a housing 1110, a housing cover 1111, a piping portion 1120, a discharge head 1130, a nozzle body 1140, and a thin film-type pressure sensor 1150.

The housing 1110 may have an internal space having one open surface, and the housing cover 1111 may be disposed on the one open surface of the housing 1110.

The internal space provided by the housing 1110 and the housing cover 1111 may have the piping portion 1120 and the nozzle body 1140, and a plurality of thin film-type pressure sensors 1150 may be inserted into a space between the nozzle body 1140 and the housing cover 1111.

The piping portion 1120 may include a chemical liquid pipe (not illustrated) supplying a chemical liquid to the discharge head 1130, and a constant-temperature water pipe (not illustrated) supplying constant-temperature water so as to maintain the chemical liquid pipe within a predetermined temperature range. In an example embodiment, the piping portion 1120 may have a dual-pipe structure in which the chemical liquid pipe is disposed in the constant-temperature water pipe.

When a coupling structure between the housing 1110 and the housing cover 1111 becomes loose, constant-temperature water may leak from the constant-temperature water pipe, causing liquid leakage. Accordingly, it may be necessary to monitor pressure of the internal space of the housing 1110 so as to maintain the pressure at a predetermined pressure.

The discharge head 1130 may be disposed in a lower portion of the housing 1110, may be connected to the chemical liquid pipe to receive the chemical liquid, and may be fixed to the nozzle body 1140 to discharge the chemical liquid to an upper surface of a substrate.

In addition, a fastening member A may be provided as a plurality of fastening members A to couple the housing cover 1111 to the nozzle body 1140. More specifically, the fastening members A may couple the housing 1110, the nozzle body 1140, and the housing cover 1111 to each other. In an example embodiment, the fastening members A may be implemented as bolts, screws, or the like.

The thin film-type pressure sensor 1150 may be inserted into a space between the nozzle body 1140 and the housing cover 1111. The thin film-type pressure sensor 1150 may be provided as one thin film-type pressure sensor 1150 or a plurality of thin film-type pressure sensors 1150, and the plurality of thin film-type pressure sensors 1150 may be disposed to be spaced apart from each other between the nozzle body 1140 and the housing cover 1111. Measurement values of the thin film-type pressure sensors 1150 may be transmitted to the control portion 1300.

When the thin film-type pressure sensors 1150 are provided as a plurality of thin film-type pressure sensors 1150, the plurality of thin film-type pressure sensors 1150 may be disposed on one surface of the housing cover to be spaced apart from each other, and the thin film-type pressure sensor 1150 may measure a degree of coupling of a fastening member around the thin film-type pressure sensor 1150. Accordingly, based on a measurement value of each of the thin film-type pressure sensors 1150, a degree of coupling of a fastening member around a corresponding sensor may be determined.

The storage portion 1200 may match the plurality of thin film-type pressure sensors 1150 with fastening members respectively disposed around the plurality of thin film-type pressure sensors 1150, and may store the matched information.

The control portion 1300 may monitor whether the nozzle body 1140 and the housing cover 1111 are airtightly coupled to each other, based on measurement values of the plurality of thin film-type pressure sensors 1150. More specifically, the control portion 1300 may determine, based on the measurement values, whether the measurement values are within a normal pressure range, may determine the thin film-type pressure sensors 1150 as normal sensors when the measurement values are within the normal pressure range, and may determine the thin film-type pressure sensors 1150 as abnormal sensors when the measurement values exceed the normal pressure range.

In an example embodiment, the thin film-type pressure sensor 1150 may be provided as three thin film-type pressure sensors 1150, and may be respectively disposed on a left portion, a central portion, and a right portion of the housing cover. When a measurement value of a thin film-type pressure sensor 1150, disposed on the left portion of the housing cover, is detected to fall below a predetermined pressure, a fastening member, coupled to the left portion of the housing, may be tightened to increase coupling force.

The display portion 1400 may receive information on fastening members disposed around the thin film-type pressure sensors 1150 determined as the abnormal sensors from the control portion 1300, and may display the information for user verification.

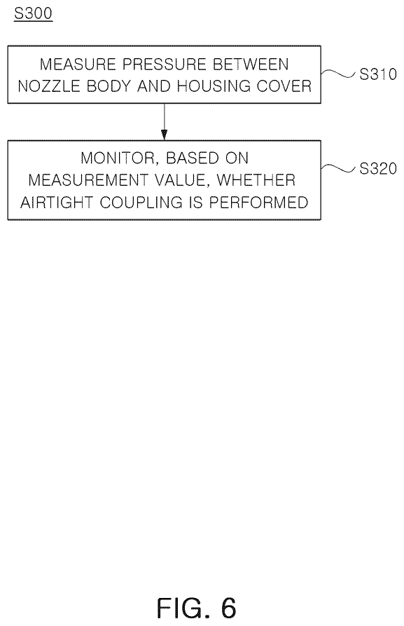

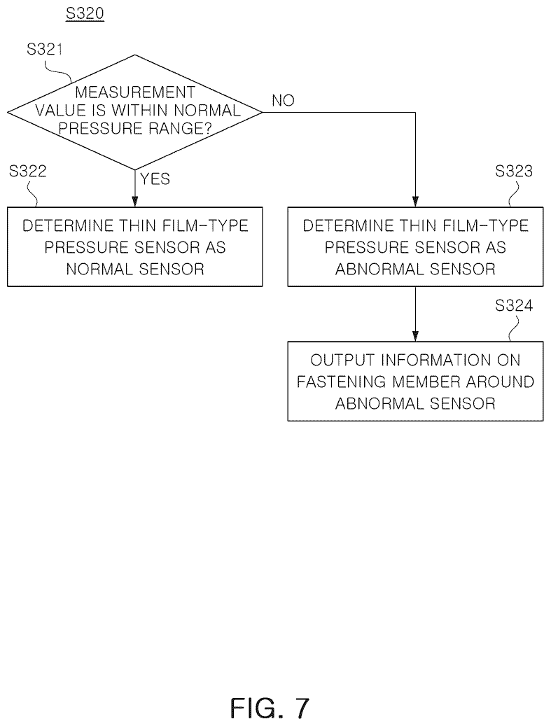

FIG. 6 is a flowchart of a method of monitoring a liquid supply apparatus according to an example embodiment of the present disclosure. FIG. 7 is a more detailed flowchart of operation S320 of FIG. 6.

Referring to FIGS. 6 and 7, a method (S300) of monitoring a liquid supply apparatus according to an example embodiment of the present disclosure may include a pressure measurement operation (S310) and an operation of monitoring whether airtight coupling is performed (S320).

In S310, a plurality of thin film-type pressure sensors 1150 may measure pressure between a nozzle body and a housing cover. In S320, the control portion 1300 may monitor whether the nozzle body and the housing cover are airtightly coupled to each other, based on measurement values of the plurality of thin film-type pressure sensors 1150.

More specifically, the control portion 1300 may determine whether the measurement values of the thin film-type pressure sensors 1150 are within a normal pressure range (S321). When the measurement values are within the normal pressure range, the control portion 1300 may determine the thin film-type pressure sensors 1150 as normal sensors (S322). When the measurement values are outside the normal pressure range, the control portion 1300 may determine the thin film-type pressure sensors 1150 as abnormal sensors (S323). The normal pressure range may include a normal pressure value or a normal pressure deviation value.

The control portion 1300 may output information on fastening members disposed around the thin film-type pressure sensors 1150 determined as the abnormal sensors, based on information stored in a storage portion 1200 (S324), and may transmit the information to a display portion 1400. The display portion 1400 may receive the information on the fastening members disposed around the thin film-type pressure sensors 1150 determined as the abnormal sensors from the control portion 1300, and may display the information for user verification.

In an example embodiment, a user may verify a position of a fastening member having an abnormality through a user terminal or monitor, may visually verify a degree of coupling of the fastening member, and may take measures to prevent liquid leakage from a nozzle unit 1100.

While example embodiments have been shown and described above, it will be apparent to those skilled in the art that modifications and variations could be made without departing from the scope of the present disclosure as defined by the appended claims.

1. A liquid supply apparatus comprising:
a nozzle unit including a nozzle body, a housing cover coupled to the nozzle body by a plurality of fastening members, and a plurality of thin film-type pressure sensors inserted between the nozzle body and the housing cover; and
a control portion configured to monitor whether the nozzle body and the housing cover are airtightly coupled to each other, based on measurement values of the plurality of thin film-type pressure sensors.

2. The liquid supply apparatus of claim 1, wherein the plurality of thin film-type pressure sensors are disposed to be spaced apart from each other between the nozzle body and the housing cover.

3. The liquid supply apparatus of claim 2, wherein the nozzle unit further includes:
a housing having an internal space having one open surface;
a discharge head configured to discharge a chemical liquid; and
a piping portion provided in the internal space, the piping portion including a chemical liquid pipe configured to supply the chemical liquid to the discharge head.

4. The liquid supply apparatus of claim 3, wherein the piping portion further includes a constant-temperature water pipe configured to supply constant-temperature water so as to maintain the chemical liquid pipe within a predetermined temperature range.

5. The liquid supply apparatus of claim 4, wherein the fastening members are configured to couple the housing, the nozzle body, and the housing cover to each other.

6. The liquid supply apparatus of claim 5, wherein the control portion is configured to:
determine whether the measurement values are within a normal pressure range, based on the measurement values;
determine the thin film-type pressure sensors as normal sensors, when the measurement values are within the normal pressure range; and
determine the thin film-type pressure sensors as abnormal sensors, when the measurement values are outside the normal pressure range.

7. The liquid supply apparatus of claim 6, further comprising:
a storage portion configured to match the plurality of thin film-type pressure sensors with fastening members respectively disposed around the plurality of thin film-type pressure sensors, and to store the matched information.

8. The liquid supply apparatus of claim 7, wherein the control portion is further configured to output information on fastening members disposed around the thin film-type pressure sensors determined as the abnormal sensors, based on information stored in the storage portion.

9. The liquid supply apparatus of claim 8, further comprising:
a display portion configured to receive the information on fastening members disposed around the thin film-type pressure sensors determined as the abnormal sensors from the control portion, and to display the information for user verification.

10. The liquid supply apparatus of claim 6, wherein the normal pressure range includes a normal pressure value or a normal pressure deviation value.

11-14. (canceled)

15. A liquid supply apparatus comprising:
a treatment container having a treatment space for a substrate;
a support portion provided in the treatment space, the support portion configured to support the substrate;
a nozzle unit including a nozzle body, a housing cover coupled to the nozzle body by a plurality of fastening members, and a plurality of thin film-type pressure sensors inserted between the nozzle body and the housing cover; and
a control portion configured to monitor whether the nozzle body and the housing cover are airtightly coupled to each other, based on measurement values of the plurality of thin film-type pressure sensors.

16. The liquid supply apparatus of claim 15, wherein the plurality of thin film-type pressure sensors are disposed to be spaced apart from each other between the nozzle body and the housing cover.

17. The liquid supply apparatus of claim 16, wherein the nozzle unit further includes:
a housing having an internal space having one open surface;
a discharge head configured to discharge a chemical liquid; and
a piping portion provided in the internal space, the piping portion including a chemical liquid pipe configured to supply the chemical liquid to the discharge head.

18. The liquid supply apparatus of claim 17, wherein the piping portion further includes a constant-temperature water pipe configured to supply constant-temperature water so as to maintain the chemical liquid pipe within a predetermined temperature range.

19. The liquid supply apparatus of claim 18, wherein the fastening members are configured to couple the housing, the nozzle body, and the housing cover to each other.

20. The liquid supply apparatus of claim 19, wherein the control portion is configured to:
determine whether the measured values are within a normal pressure range, based on the measured values;
determine the thin film-type pressure sensors as normal sensors, when the measured values are within the normal pressure range; and
determine the thin film-type pressure sensors as abnormal sensors, when the measured values are outside the normal pressure range.
